(19) United States
(12) Patent Application Publication
(10) Pub. No.: US 2012/0187569 A1
(43) Pub. Date: Jul. 26, 2012

(54) SEMICONDUCTOR DEVICE AND METHOD OF MANUFACTURING SAME

(75) Inventors: Yumi HAYASHI, Yokohama-Shi (JP); Akihiro KAJITA, Yokohama-Shi (JP); Makoto WADA, Yokohama-Shi (JP)

(73) Assignee: Kabushiki Kaisha Toshiba, Tokyo (JP)

(21) Appl. No.: 13/336,247

(22) Filed: Dec. 23, 2011

(30) Foreign Application Priority Data
Jan. 25, 2011 (JP) 2011-013298

(51) Int. Cl. H01L 23/48; H01L 21/768

(52) U.S. Cl. 257/774; 438/675; 257/E23.011; 257/E21.586

(57) ABSTRACT

According to one embodiment, a semiconductor device includes a first insulating film formed on a substrate and including a first area and a second area; a groove formed in the first area of the first insulating film; a plurality of first wiring lines formed in the groove and on the first insulating film, and a second insulating film covering a top surface of the first insulating film and top surfaces of the first wiring lines, the plurality of first wiring lines are parallel to a sidewall of the groove and apart from each other with a first predetermined distance, and the first wiring line closest to the sidewall is apart from the sidewall with a second predetermined distance.

### CROSS-REFERENCE TO RELATED APPLICATION

This application is based upon and claims the benefit of priority from prior Japanese Patent Application No. 2011-13298 filed on Jan. 25, 2011, the entire contents of which are incorporated herein by reference.

### FIELD

Embodiments of the present invention relate to a semiconductor device and a manufacturing method thereof.

### BACKGROUND

In a multilayer wiring line that is included in a semiconductor device such as a memory product and a logic product, minuteness and diversification of a structure have advanced. With regard to a method of forming the multilayer wiring line, a method is studied which forms wiring lines using a reactive ion etching (RIE) method and forms an insulating film to bury portions between the wiring lines.

When the wiring lines are formed using the RIE method, a wiring material is deposited on the entire surface of a substrate where the wiring lines need to be formed and the wiring material of portions other than portions that become the wiring lines is removed using the RIE method. Therefore, since the deposited wiring material is completely removed using the RIE method from a non-wiring area of the substrate where the wiring lines are not formed, the wiring material removed from a wiring area where the wiring lines are formed is different in volume from the wiring material removed from the non-wiring area. As a result, a residue of the wiring material may be generated in the non-wiring area and a short circuit may be generated due to the residue in the semiconductor device.

In addition, it may become difficult to shape the wiring line in a boundary portion of the wiring area and the non-wiring area into a desired shape, that is, the shape of the wiring lines that are formed in the boundary portion may become different from the shape of the other wiring lines in the wiring area. In addition, it may become difficult to control the height and the shape of the wiring lines due to the difference in the volume of the wiring material removed using the RIE method, from the wiring area.

After the wiring lines are formed, the insulating film is formed to bury the portions between the wiring lines. However, the insulating film is formed on both of the wiring area where the wiring lines are present and the non-wiring area where no wiring lines are present. For this reason, a step may be generated on the surface of the insulating film. If the step is generated in the insulating film, it becomes difficult to improve the precision of a lithographic process that will be executed thereafter. Accordingly, a chemical mechanical polishing (CMP) process needs to be executed to flatten the surface of the insulating film after the insulating film is formed.

### BRIEF DESCRIPTION OF THE DRAWINGS

FIGS. 1A to 1F are cross-sectional views illustrating a process of manufacturing a semiconductor device according to a first embodiment;

FIG. 2 is a cross-sectional view of the semiconductor device according to the first embodiment;

FIGS. 3 to 9 are cross-sectional views of semiconductor devices according to first to fifth modifications of the first embodiment;

FIGS. 10A to 10F are cross-sectional views illustrating a process of manufacturing the semiconductor device according to the fifth modification of the first embodiment;

FIGS. 11A and 11B are cross-sectional views illustrating a process of manufacturing a semiconductor device according to a second embodiment;

FIG. 12 is a cross-sectional view of the semiconductor device according to the second embodiment;

FIG. 13 is a cross-sectional view of a semiconductor device according to a modification of the second embodiment;

FIG. 14 is a cross-sectional view of a semiconductor device according to a third embodiment;

FIG. 15 is a cross-sectional view of a semiconductor device according to a modification of the third embodiment; and

FIGS. 16A to 16E are cross-sectional views illustrating a process of manufacturing the semiconductor device according to the third embodiment.

### DETAILED DESCRIPTION

In one embodiment, a semiconductor device includes a first insulating film formed on a substrate and including a first area and a second area; a groove formed in the first area of the insulating film; a plurality of first wiring lines formed in the groove and on the insulating film, the plurality of first wiring lines being parallel to a sidewall of the groove and being apart from each other with a first predetermined distance, and the first wiring line closest to the sidewall being apart from the sidewall with a second predetermined distance; and a second insulating film covering a top surface of the first insulating film and top surfaces of the first wiring lines.

Hereafter, embodiments will be described with reference to the drawings. However, the present invention is not limited to the embodiments. Like reference numerals refer to like elements in all of the drawings and the redundant description will not be repeated. In addition, the drawings are schematic views to promote explanation of the present invention and the understanding thereof, and the shapes, dimensions, and ratios thereof may be different from those of real devices. However, a design can be appropriately changed in consideration of the following explanation and a well-known technology.

### First Embodiment

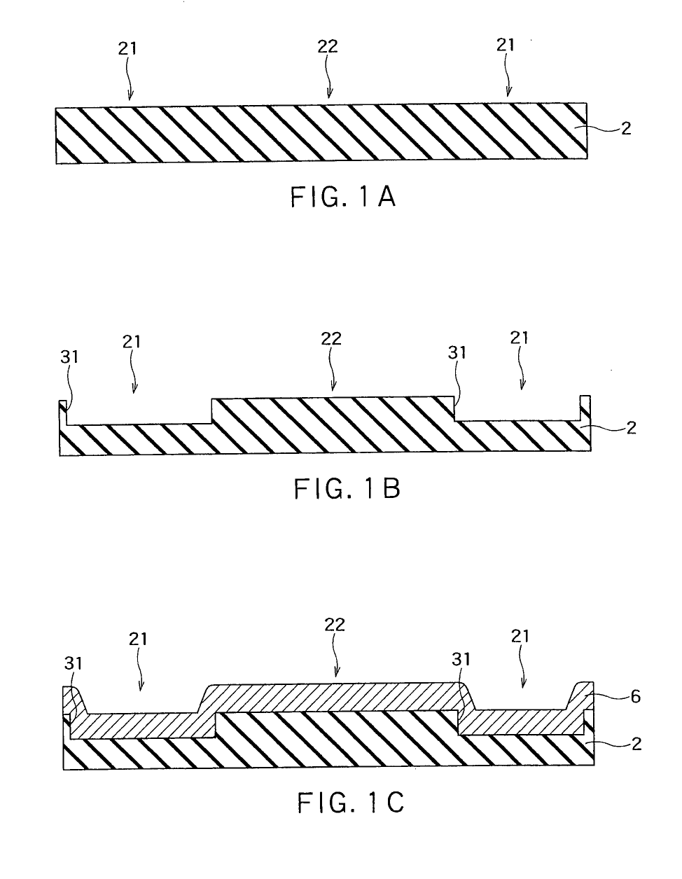

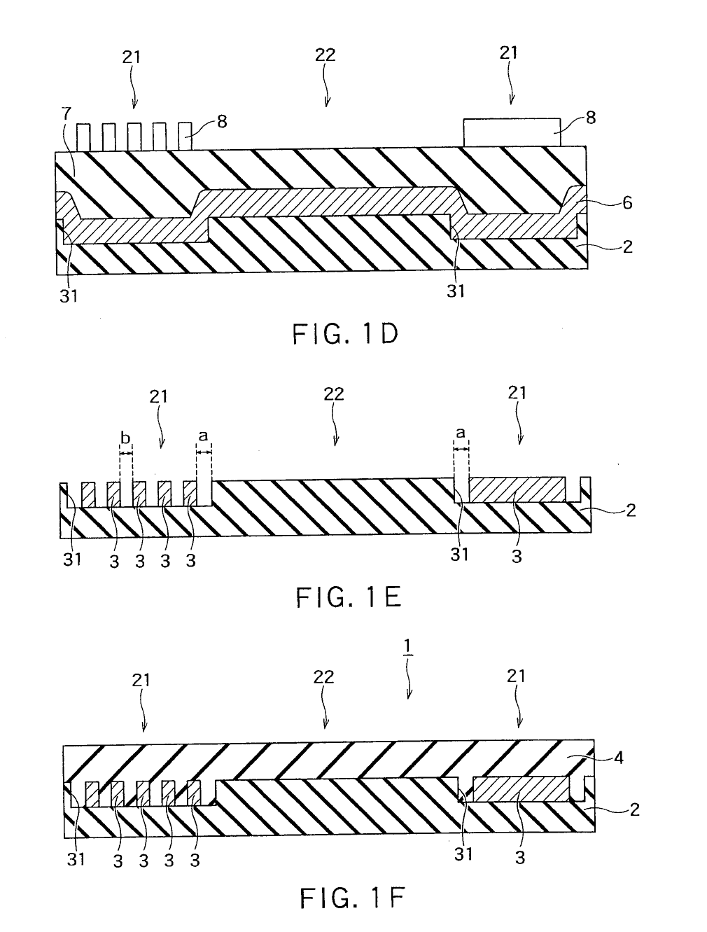

A method of manufacturing a semiconductor device according to the first embodiment will be described using FIGS. 1A to 1F. Hereinafter, a method of manufacturing a semiconductor device such as a memory product and a logic product in which an insulating film to bury portions between wiring lines is formed after the wiring lines are formed using an RIE method will be described. However, the present invention is not limited to this kind of semiconductor device and can be used in a method of manufacturing a semiconductor device of a different kind. First, as illustrated in FIG. 1A, a first insulating film 2 is prepared. The first insulating film 2 can be formed using various insulating films such as silicon oxide, silicon nitride, silicon carbonate (SiOC), and polyacrylate (PAR). The first insulating film 2 has a wiring area 21 where wiring lines 3 are formed and a non-wiring area 22 where the wiring lines 3 are not formed.

As illustrated in FIG. 1B, a groove 31 is formed in the wiring area 21 on the first insulating film 2 using a lithographic process and an etching process. The depth of the groove 31 is preferably equal to the height of the wiring lines 3 that is formed thereafter, for example, is several tens nm. The width of the groove 31 can be set from several hundreds nm to several tens μm. In this case, the groove 31 is formed using the lithographic process requiring a high cost. However, since the width of the groove 31 is large, the lithographic process that forms the groove 31 in the wiring area 21 has the significantly long distance, as compared with the minimum distance that can be resolved by the lithography (for example, one digit or more). Therefore, the lithographic process that is used in this case requires a low cost.

Next, as illustrated in FIG. 1C, a wiring material 6 is deposited along unevenness of the groove 31 to cover an entire surface of the first insulating film 2. Examples of deposition method include a chemical vapor deposition (CVD) method, a physical vapor deposition (PVD) method, and a plating method. The thickness of the wiring material 6 can be set to be equal to the height of the formed wiring line 3, for example. The wiring material 6 can be selected from metallic materials that can be easily processed using the RIE method. For example, the wiring material 6 can be selected from metallic simple substances such as TiN, Ti, Ni, Co, W, Mo, Ru, Ta, and Al, silicide including at least one of W, Ti, Ni, and Co, and silicon where at least one of W, Ti, Ni, and Co is doped.

Next, as illustrated in FIG. 1D, a mask material 7 is deposited. The mask material 7 is processed using a resist 8 having a desired pattern and a mask is formed.

Next, as illustrated in FIG. 1E, the wiring material 6 is processed using the previously formed mask and the lithographic process and the etching process and the wiring line 3 is formed in the groove 31. The height of the wiring line 3 is, for example, several tens nm and the width thereof is, for example, several tens nm. From a viewpoint of easiness of control of formation of the wiring line 3, it is preferable to set a constant distance ‘a’ between a sidewall of the groove 31 to the wiring line 3 closest to the sidewall of the groove 31. The distance ‘a’ is preferably similar to the distance ‘b’ between the wiring lines 3. For example, the distance ‘b’ may be set to ten times of the distance ‘a’ or less. When the volume of the wiring material 6 removed by the etching process is not constant on the first insulating film 2, an etching residue of the wiring material 6 may be generated or a shape of the wiring line 3 may become irregular. However, in this embodiment, since the wiring material 6 is removed from almost the entire surface of the first insulating film 2, the etching residue of the wiring material 6 can be prevented from being generated and the irregularity of the shape of the wiring line 3 can be improved.

Next, as illustrated in FIG. 1F, a second insulating film 4 is formed. The second insulating film 4 can be formed using various insulating films such as silicon oxide, silicon nitride, silicon carbonate (SIOC), and polyacrylate (PAR), similar to the first insulating film 2. The thickness of the second insulating film 4 can be set to several tens nm to 1 μm, for example. Since the groove 31 is formed and the wiring lines 3 are formed in the groove 31, the height of a surface where the second insulating film 4 is formed over the entire surface of the first insulating film 2 can be equalized by a top surface of the first insulating film 2 where the groove 31 is not formed (top surface of a convex portion of the first insulating film 2) and top surfaces of the wiring lines 3. Therefore, even though the second insulating film 4 is formed on the top surfaces of the first insulating film and the wiring lines, a step can be prevented from being generated in the surface of the second insulating film 4. For this reason, a CMP process that flattens the surface of the second insulating film 4 may not be executed.

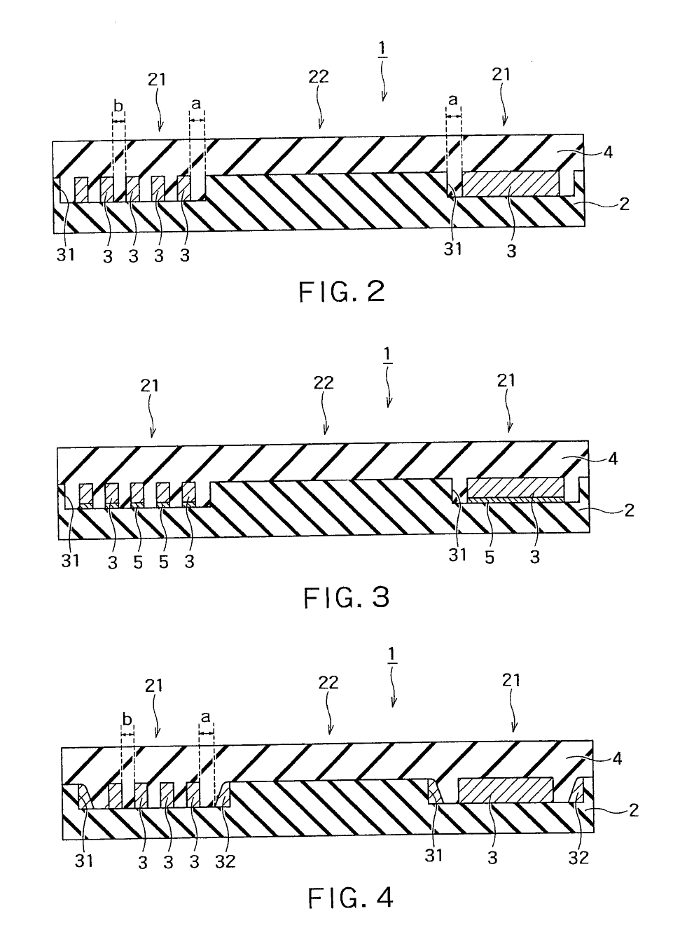

In this way, as illustrated in FIG. 2, the semiconductor device 1 according to the first embodiment is formed. That is, the semiconductor device 1 according to this embodiment has the groove 31 that is formed in the wiring area 21 of the first insulating film 2; the plural wiring lines 3 that are disposed in the groove 31 while being parallel to the sidewall/sidewalls of the groove 31 and apart from the sidewall of the groove 31; and the second insulating film 4 that is formed to cover the top surfaces of the first insulating film 2 and the plural wiring lines 3, thereby filling the gaps between the wiring lines and the portions between the sidewall of the groove 31 and the wiring lines 3 disposed adjacent to the sidewall. From a viewpoint of easiness of control of formation of the wiring line 3, the distance ‘a’ from the sidewall of the groove 31 to the wiring line 3 closest to the sidewall of the groove 31 is preferably set to be constant. The distance ‘a’ is preferably similar to the distance ‘b’ between the wiring lines 3.

As illustrated in FIG. 3, a barrier metal 5 that has the thickness of several nm may be formed below the wiring line 3. The barrier metal 5 can be formed using a material including a metallic simple substance such as TiN, Ti, Ni, Co, W, Mo, Ru, Ta, and Al. By forming the barrier metal 5, adhesion between the first insulating film 2 and the wiring lines 3 can be improved.

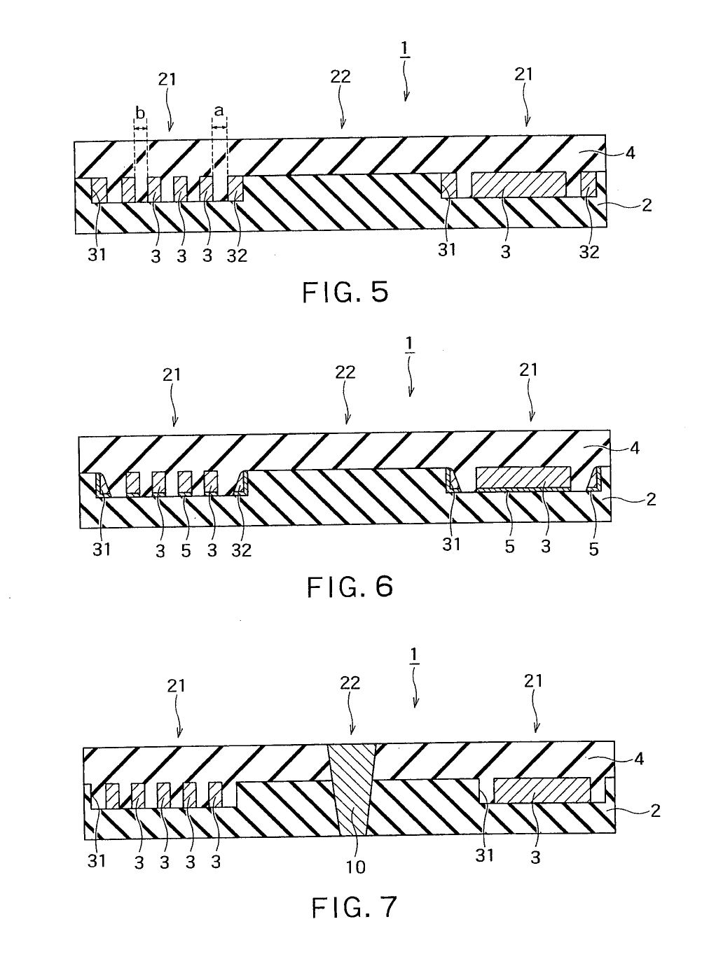

A first modification of the semiconductor device 1 according to the first embodiment is illustrated in FIGS. 4 and 5. First, if the wiring lines 3 are formed in the groove 31 formed in the first insulating film 2, a groove end wiring line 32 may be formed to contact the sidewall of the groove 31 and a part of a bottom portion of the groove 31. For example, with regard to the shape of the groove end wiring line 32, the groove end wiring line 32 may be the same in shape as the other wiring lines 3 that do not contact the groove 31 (refer to FIG. 5) or may be different from the other wiring lines 3 in cross-sectional shape (refer to FIG. 4). The cross-sectional shape of the groove end wiring line 32 is asymmetric at the left and right sides or a shape similar to a triangle. The groove end wiring line 32 may be used as the same wiring line as the other wiring lines 3. The groove end wiring line 32 may be used as a dummy wiring line. When the groove end wiring line 32 is formed, the previously defined distance ‘a’ is the distance between the groove end wiring line 32 and the wiring line 3 second closest to the sidewall of the groove 31 (refer to FIGS. 4 and 5). Similar to the first embodiment, the distance ‘a’ is preferably set to be constant. The distance ‘a’ is preferably similar to the distance ‘b’ between the wiring lines 3. For example, the distance ‘b’ may be set to 10 times of the distance ‘a’ or less.

Similar to the first embodiment, the barrier metal 5 that has, for example, the thickness of several nm may be formed to cover the top surface portion of the first insulating film 2 below the wiring line 3 and the sidewall of the groove 31, as illustrated in FIG. 6 that corresponds to a second modification of the semiconductor device according to the first embodiment. Similar to the first embodiment, the barrier metal 5 can be formed using a material including a metallic simple substance such as TiN, Ti, Ni, Co, W, Mo, Ru, Ta, and Al. By forming the barrier metal 5, adhesion between the first insulating film 2 and the wiring lines 3 can be improved.

When the wiring lines are formed using a damascene method, a dummy pattern is generally disposed on the non-wiring area 22 to execute the CMP process on the substrate. However, in this embodiment, since the CMP process does not need to be executed on the wiring material 6, the dummy pattern does not need to be disposed on the non-wiring area 22. Therefore, as illustrated in FIG. 7 that corresponds to a third modification of the semiconductor device according to the first embodiment, when the semiconductor device 1 having a contact 10 penetrating several layers is formed, the contact 10 can be formed in a convex area of the first insulating film 2, in other words, the non-wiring area 22. That is, since the dummy pattern is not provided in the non-wiring area 22, in the first embodiment and the modifications thereof, an area where the contact 10 can be disposed is wide and a degree of freedom of a design of the contact 10 becomes high.

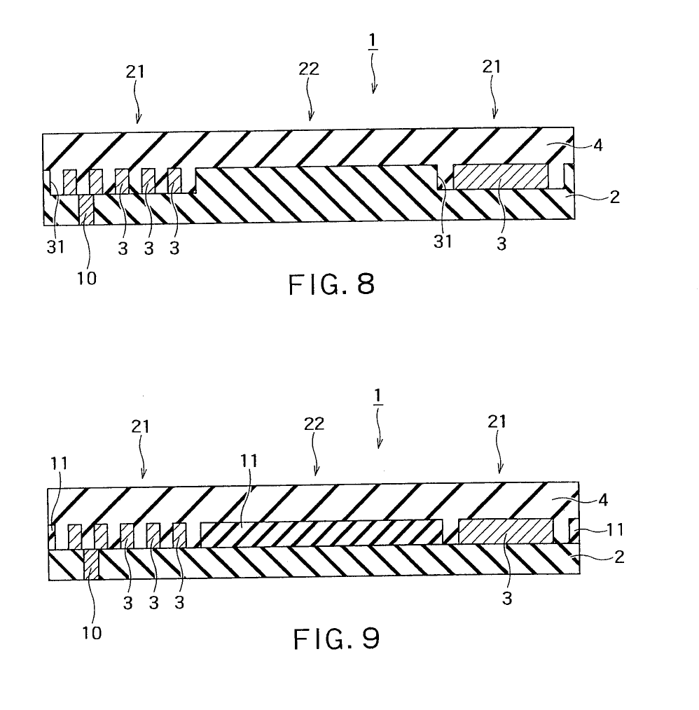

In addition, the semiconductor device 1 that has the contact 10 below the wiring line 3 can be formed. This semiconductor device 1 is illustrated in FIG. 8 as a fourth modification of the first embodiment. In the fourth modification, the contact 10 below the wiring line 3 is formed using the RIE method.

Similar to the fourth modification, when the contact 10 is formed using the damascene method in the semiconductor device 1 having the contact 10 below the wiring line 3, the semiconductor device 1 can be configured like the fifth modification of the first embodiment illustrated in FIG. 9. In the fifth modification, a groove is not formed in the first insulating film 2 and a third insulating film 11 is formed on the first insulating film 2.

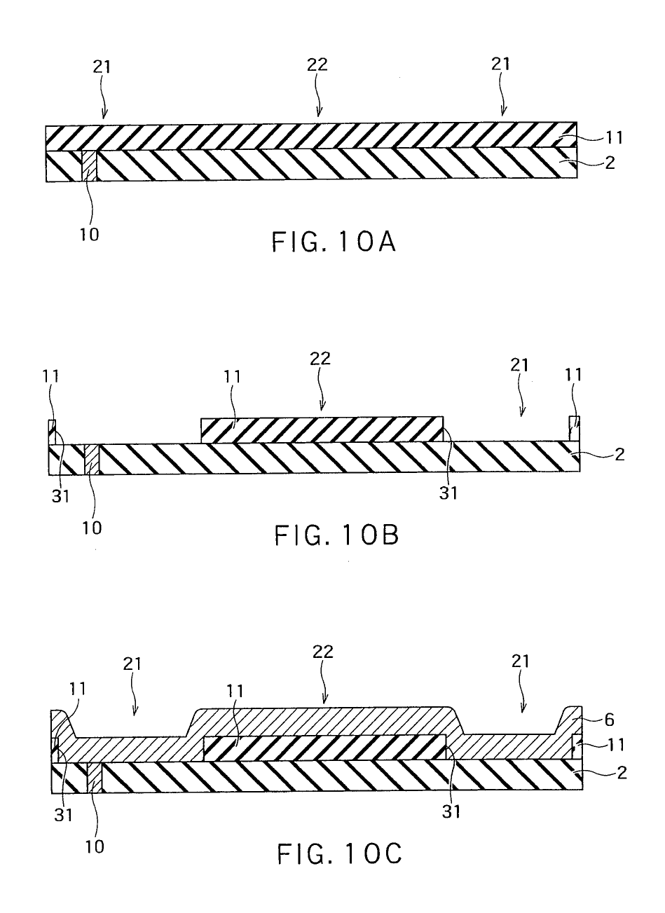

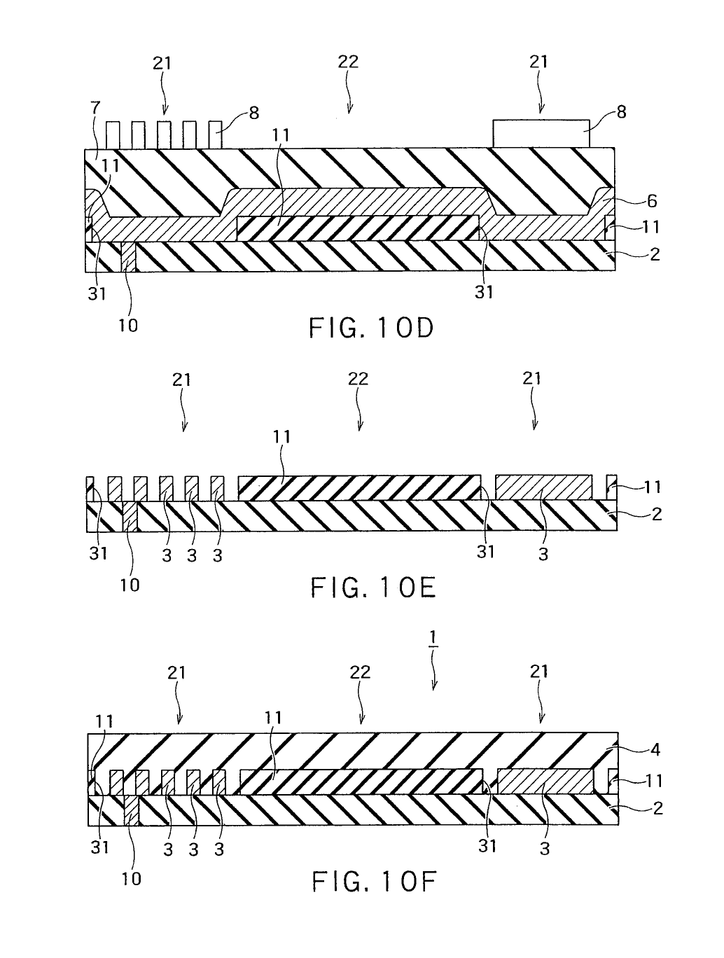

A method of manufacturing the semiconductor device according to the fifth modification will be described using FIGS. 10A to 10F. As illustrated in FIG. 10A, after the contact 10 is formed using the damascene method, in detail, the CMP process is executed on the surfaces of the contact 10 and the first insulating film 2, the third insulating film 11 is formed on the surfaces of the contact 10 and the first insulating film 2.

Next, as illustrated in FIG. 10B, a portion of the third insulating film 11 that corresponds to the wiring area 21 is removed. In this way, the first insulating film 2 and the third insulating film 11 covering the part of the surface of the first insulating film are integrated and the groove 31 is formed.

Next, as illustrated in FIG. 10C, similar to the first embodiment, the wiring material 6 is deposited along the unevenness of the groove 31 to cover the entire surfaces of the first insulating film 2 and the third insulating film 11.

Next, as illustrated in FIGS. 10D to 10F, similar to the first embodiment, the mask is formed, the wiring lines 3 are formed in the groove 31, and the second insulating film 4 is formed. Since the following manufacturing method is the same as that of the first embodiment, the description thereof will not be repeated here.

As such, according to this embodiment, in the semiconductor device where the wiring lines are formed using the RIE method, the wiring lines 3 are formed in the groove 31 previously formed in the first Insulating film 2 and the wiring material 6 is equally removed from the entire surface. Therefore, control of the shape of the wiring lines 3 becomes easy and the height of the surface where the second insulating film 4 is formed is equalized by the top surface of the first insulating film 2 where the groove 31 is not formed (top surface of the convex portion of the first insulating film 2) and the top surfaces of the wiring lines 3. As a result, the step can be prevented from being generated on the surface of the second insulting film 4 formed on the top surfaces.

### Second Embodiment

A semiconductor device according to a second embodiment is a semiconductor device 1 where air gaps 12 are formed between the wiring lines 3. By forming the air gaps 12 between wiring lines 3, the parasitic capacity that is generated between the wiring lines 3 can be decreased.

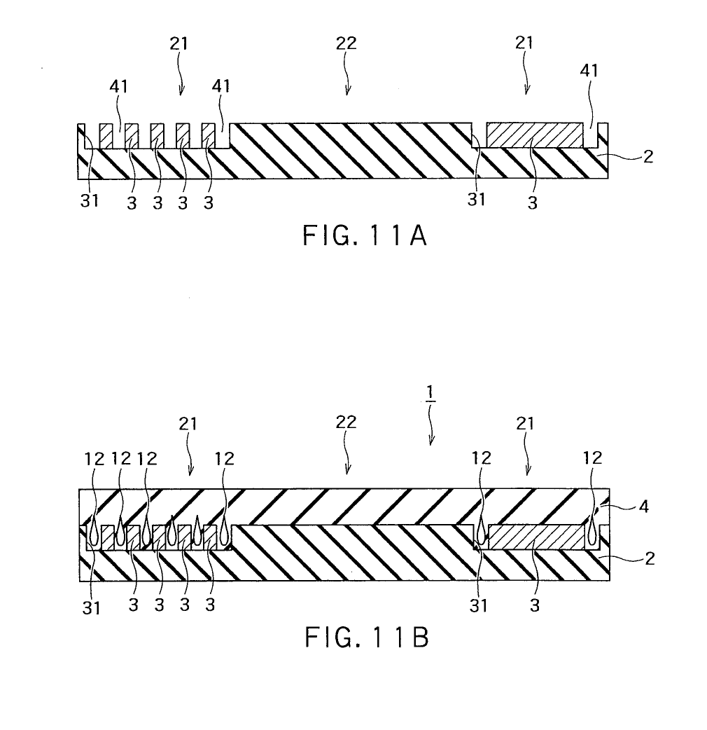

A method of manufacturing the semiconductor device 1 according to the second embodiment will be described using FIGS. 11A and 11B.

As illustrated in FIG. 11A, similar to the first embodiment, the groove 31 is previously formed in a wiring area 21 of the first insulating film 2. At this time, the groove 31 is formed such that the width of a space 41 buried with a second insulating film 4 is approximately equalized over the entire first insulating film 2. In detail, the groove 31 is formed such that the portions between the wiring lines 3 and the portion between the sidewall of the groove 31 and the wiring line 3 closest to the sidewall of the groove 31 have the same width.

As illustrated in FIG. 11B, the second insulating film 4 that has the air gaps 12 is formed to bury the groove 31.

Therefore, the air gaps 12 can be formed only between the wiring lines 3 which are desired to decrease the capacity, without controlling the manufacturing process such that the air gaps 12 are not formed between the wiring lines 3, by additionally executing the lithographic process with respect to a non-wiring area 22 or the wiring area where the reduction of the capacity is not needed or by optimizing the film forming conditions of the second insulating film 4. Since the width of the space 41 buried with the second insulating film 4 can be equalized over the entire first insulating film 2, the air gaps 12 can be formed equally over the entire second insulating film 4 buried in the space 41, in detail, the air gaps 12 can be formed in a state in which the shape, the size, and the distribution of the air gaps 12 are equalized. Since the air gaps 12 can be equally formed, the manufacturing process can be controlled to form the air gaps 12 that can greatly decrease the capacity, and a situation where the air gaps 12 are not closed or a situation where the wiring lines 3 are thermally expanded by heating and the wiring lines 3 fall down to the side of the air gaps 12 in the process of manufacturing the semiconductor device 1 thereafter can be avoided, and a manufacturing yield of the semiconductor device 1 can be improved.

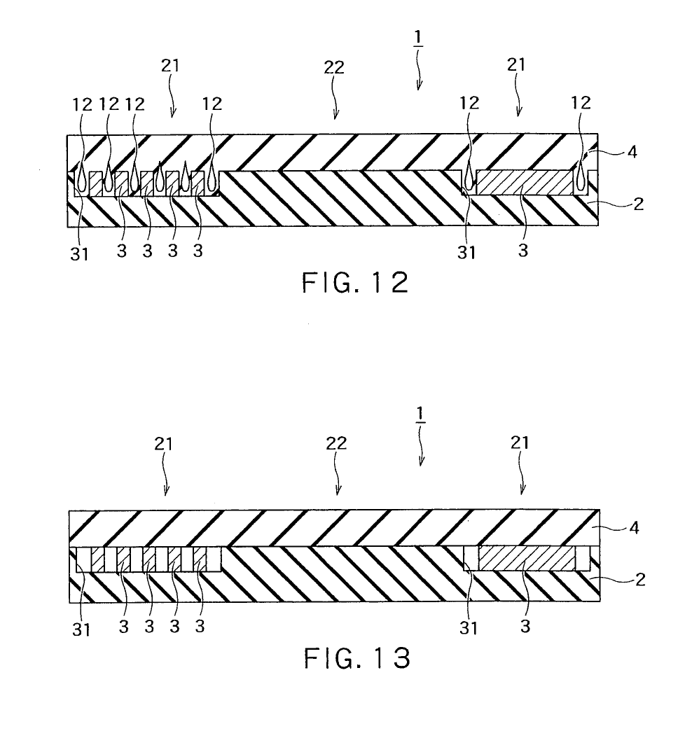

In this way, as illustrated in FIG. 12, the semiconductor device 1 according to the second embodiment is formed. That is, the semiconductor device 1 where the air gaps 12 are formed in the second insulating film 4 between the wiring lines 3 and between the sidewall of the groove 31 and the wiring line 3 closest to the sidewall is formed. As can be seen from FIG. 12, in this embodiment, the space 41 in which the second insulating film 4 is buried has the same width as the distance between the wiring lines 3. Therefore, the strength of the semiconductor device 1 can be further secured, as compared with the case where the second insulating film 4 having the air gaps 12 is buried simultaneously in a narrow space such as the space between the wiring lines 3 and a space wider than the space.

As illustrated in FIG. 13, the semiconductor device 1 may be formed not to bury the second insulating film 4 between the wiring lines 3 at all. In the semiconductor device 1, since the first insulating film 2 exists in the non-wiring area 22, the capacity between the wiring lines 3 can be greatly decreased while the strength of the semiconductor device 1 can be secured.

As such, according to this embodiment, in the semiconductor device 1 where the wiring lines are formed using the RIE method, the wiring lines 3 are formed in the groove 31 previously formed in the first insulating film 2 and the wiring material 6 is equally removed from the entire surface. Therefore, control of the shape of the wiring lines 3 becomes easy and the height of the surface where the second insulating film 4 is formed is equalized by the top surface of the first insulating film 2 where the groove 31 is not formed (top surface of the convex portion of the first insulating film 2) and the top surface of the wiring line 3. As a result, the step can be prevented from being generated on the surface of the second insulting film 4 formed on the top surfaces. According to this embodiment, since the air gaps 12 can be formed equally over the entire surface, the capacity generated between the wiring lines 3 can be decreased while a manufacturing yield of the semiconductor device 1 can be improved. In addition, the strength of the semiconductor device 1 can be secured.

Similar to the first embodiment, the barrier metal 5 that has the thickness of several nm may be formed below the wiring line 3, for example. The barrier metal 5 can be formed using a material including a metallic simple substance such as TiN, Ti, Ni, Co, W, Mo, Ru, Ta, and Al.

### Third Embodiment

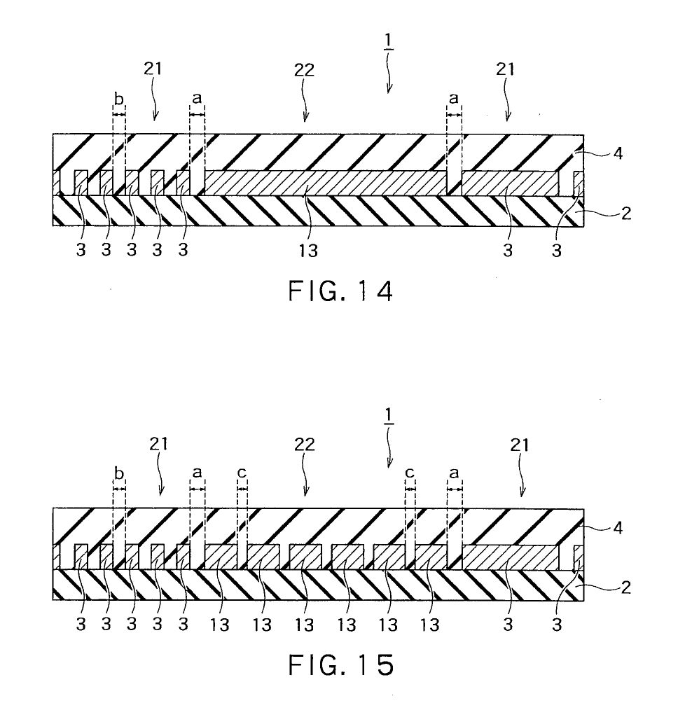

According to a third embodiment, as illustrated in FIG. 14, since a dummy pattern 13 is disposed on a non-wiring area 22 and wiring lines 3 and the dummy pattern 13 are disposed over almost the entire surface of first insulating film 2, the surface of the second insulating film 4 that is formed on the wiring lines and the dummy pattern can be flattened. The third embodiment can be applied to the semiconductor device 1 where the contact 10 striding over several layers is not provided.

In this embodiment, similar to the first embodiment, from a viewpoint of easiness of control of formation of the wiring lines 3, it is preferable that the distance ‘a’ from the wiring line 3 to the dummy pattern 13 formed in the non-wiring area 22 closest to the wiring line 3 be constant and be not ten times the distance ‘b’ between the wiring lines 3 or more (refer to FIG. 14).

The dummy pattern 13 according to this embodiment may be divided with a constant period, as illustrated in FIG. 15 that corresponds to a cross-sectional view of a modification of the semiconductor device 1 according to the third embodiment. From a viewpoint of easiness of control of formation of the wiring line 3, the distance between the dummy patterns 13 is preferably equal to the distance ‘a’ between the wiring line 3 and the dummy pattern 13 closest to the wiring lines 3.

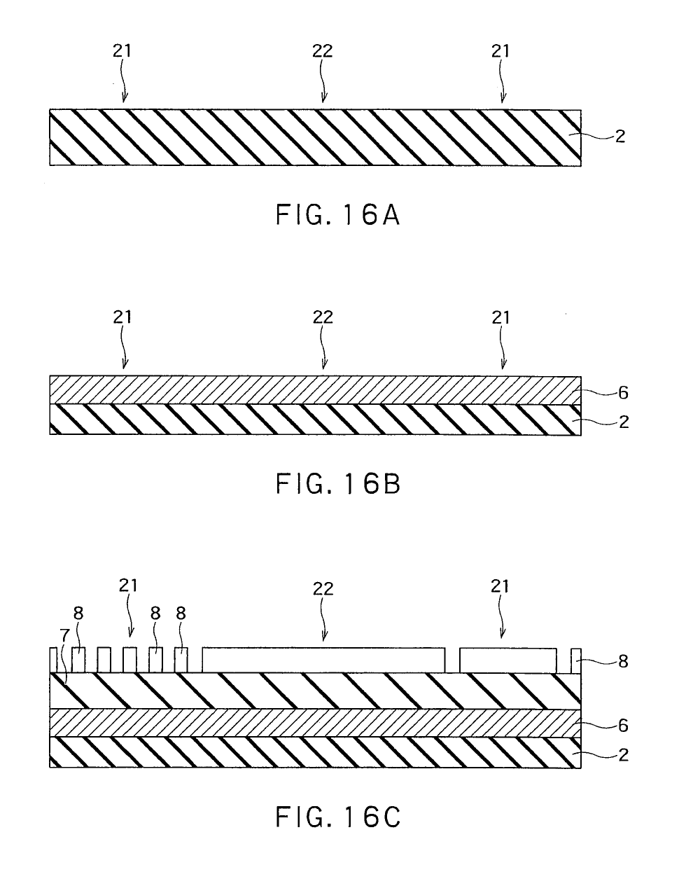

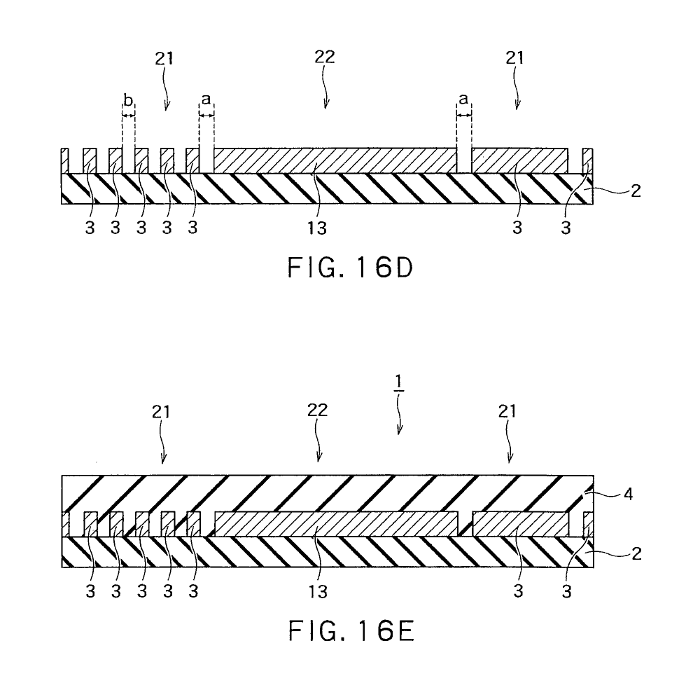

A method of manufacturing the semiconductor device 1 according to the third embodiment will be described using FIGS. 16A to 16E.

First, as illustrated in FIG. 16A, similar to the first embodiment, the first insulating film 2 is prepared. The first insulating film 2 has a wiring area 21 where the wiring lines 3 are formed and a non-wiring area 22 where the dummy pattern 13 is formed.

Next, as illustrated in FIG. 16B, the wiring material 6 is deposited to cover an entire surface of the first insulating film 2. As a deposition method, similar to the first embodiment, the CVD method, the PVD method, and the plating method are used. The thickness of the wiring material 6 can be set to be equal to the height of the formed wiring line 3, for example. The wiring material 6 can be selected from metallic materials that can be easily processed using the RIE method. For example, the wiring material 6 can be selected from metallic simple substances such as TiN, Ti, Ni, Co, W, Mo, Ru, Ta, and Al, silicide including at least one of W, Ti, Ni, and Co, and silicon where at least one of W, Ti, Ni, and Co is doped.

Next, as illustrated in FIG. 16C, a mask material 7 is deposited. The mask material 7 is processed using the resist 8 having a desired pattern and a mask is formed.

Next, as illustrated in FIG. 16D, the wiring material 6 is processed using the previously formed mask by the lithographic process and the etching process and the wiring lines 3 and the dummy pattern 13 are formed on the first insulating film 2. As described above, it is preferable that the distance ‘a’ from the wiring line 3 to the dummy pattern 13 formed in the non-wiring area 22 closest to the wiring line 3 be constant and be not ten times the distance ‘b’ between the wiring lines 3 or more. In this embodiment, the wiring material 6 is rarely removed by the etching process. In other words, the volume of the wiring material 6 that is removed by the etching process is almost constant over the entire surface of the first insulating film 2. Therefore, control of the shape of the wiring line 3 becomes easy.

Next, as illustrated in FIG. 16E, similar to the first embodiment, the second insulating film 4 is formed. Since the dummy pattern 13 is disposed in the non-wiring area 22 and the wiring lines 3 and the dummy pattern 13 are disposed over almost the entire surface of the first insulating film 2, the surface of the second insulating film 4 that is formed on the wiring lines and the dummy pattern can be flattened.

As such, according to this embodiment, in the semiconductor device 1 where the wiring lines 3 are formed using the RIE method, by disposing the wiring lines 3 in the wiring area 21 and disposing the dummy pattern 13 in the non-wiring area 22, the wiring lines 3 and the dummy pattern 13 are disposed over almost the entire surface of the first insulating film 2. Therefore, the surface of the second insulating film 4 that is formed on the wiring lines and the dummy pattern can be flattened. Since the wiring material 6 can be equally removed from the entire surface, control of the shape of the wiring line 3 becomes easy.

Similar to the first embodiment, the barrier metal 5 that has, for example, the thickness of several nm may be formed below the wiring line 3. The barrier metal 5 can be formed using a material including a metallic simple substance such as TiN, Ti, Ni, Co, W, Mo, Ru, Ta, and Al.

In the first to third embodiments, the semiconductor substrate may not be the silicon substrate and may be other substrate. In addition, the semiconductor substrate may have the configuration where a semiconductor structure is formed on various substrates.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first insulating film formed on a substrate and including a first area and a second area;
a groove formed in the first area of the first insulating film;
a plurality of first wiring lines formed in the groove and on the first insulating film, the plurality of first wiring lines being parallel to a sidewall of the groove and being apart from each other with a first predetermined distance, and the first wiring line closest to the sidewall being apart from the sidewall with a second predetermined distance; and
a second insulating film covering a top surface of the first insulating film and top surfaces of the first wiring lines.

2. The semiconductor device of claim 1,
wherein the second predetermined distance is ten times of the first predetermined distance or less.

3. The semiconductor device of claim 1, further comprising:
a barrier metal formed between a bottom surface of the groove and the first wiring lines.

4. The semiconductor device of claim 1,
wherein the depth of the groove is equal to the height of the plurality of first wiring lines.

5. The semiconductor device of claim 1, further comprising:
a contact formed in the second area of the first insulating film.

6. The semiconductor device of claim 1,
wherein the second insulating film is buried between the first wiring lines, and between the sidewall and the first wiring line.

7. The semiconductor device of claim 1,
wherein air gaps are formed between the first wiring lines, and between the sidewall and the first wiring line.

8. The semiconductor device of claim 1,
wherein the plurality of first wiring lines are parallel to the sidewalls of the groove, and the first wiring lines closest to the sidewalls are apart from the sidewalls with a second predetermined distance.

9. The semiconductor device of claim 1, further comprising:
a pair of second wiring lines contacting the sidewalls of the groove.

10. The semiconductor device of claim 9,
wherein the second wiring lines are apart from the first wiring lines with a third predetermined distance.

11. The semiconductor device of claim 10,
wherein the third predetermined distance is ten times of the first predetermined distance or less.

12. The semiconductor device of claim 9,
wherein the first wiring lines and the pair of second wiring lines have the same cross-sectional shape.

13. The semiconductor device of claim 9,
wherein the first wiring lines and the pair of second wiring lines have different cross-sectional shapes.

14. A semiconductor device comprising:
a first insulating film formed on a substrate and including a first area and a second area;
a plurality of third wiring lines formed in the first area of the first insulating film;
a dummy wiring line formed in the second area of the first insulating film; and
a second insulating film covering a top surface of the first insulating film, top surfaces of the plurality of third wiring lines, and a top surface of the dummy wiring line,
wherein the plurality of third wiring lines are part from each other with a fourth predetermined distance,
the third wiring lines closest to the dummy wiring line are apart from the dummy wiring line with a fifth predetermined distance, and
the fifth predetermined distance is ten times of the fourth predetermined distance or less.

15. The semiconductor device of claim 14,
wherein a plurality of dummy wiring lines are formed,
the plurality of dummy wiring lines are apart from each other with a sixth predetermined distance, and
the sixth predetermined distance is equal to the fifth predetermined distance.

16. A method of manufacturing a semiconductor device, comprising:
forming a groove in a first area, a first insulating film including the first area and a second area;
depositing a wiring material to cover a top surface of the first insulating film, a bottom surface of the groove, and each sidewall of the groove;
forming a plurality of first wiring lines parallel to a sidewall of the groove, by etching the wiring material, the plurality of first wiring lines being apart from each other with a seventh predetermined distance, and the first wiring line closest to the sidewall being apart from the sidewall with an eighth predetermined distance; and
forming a second insulating film to cover the top surface of the first insulating film and top surfaces of the plurality of first wiring lines.

17. The method of claim 16,
wherein the forming of the plurality of first wiring lines is performed such that the eighth predetermined distance becomes ten times of the seventh predetermined distance or less.

18. The method of claim 16,
wherein the forming of the second insulating film is performed such that air gaps are formed between the first wiring lines and between the sidewall and the first wiring line.

19. The method of claim 16, further comprising:
forming a pair of second wiring lines contacting each of the sidewalls in the first area of the first insulating film, by etching the wiring material.

20. The method of claim 19,
wherein the forming of the pair of second wiring lines is performed such that the distance between the second wiring line and the first wiring line becomes a ninth predetermined distance.
